(19) United States
(12) Patent Application Publication
(10) Pub. No.: US 2025/0273499 A1
(43) Pub. Date: Aug. 28, 2025

(54) ELECTROSTATIC CHUCK FOR NON-PLANAR SUBSTRATES

(71) Applicant: Applied Materials, Inc., Santa Clara, CA (US)

(72) Inventor: Vijay D. PARKHE, San Jose, CA (US)

(21) Appl. No.: 19/051,244

(22) Filed: Feb. 12, 2025

Related U.S. Application Data
(60) Provisional application No. 63/559,056, filed on Feb. 28, 2024.

(51) Int. Cl. H01L 21/683

(52) U.S. Cl. CPC H01L 21/6833

(57) ABSTRACT

Embodiments of the disclosure include an electrostatic chuck (ESC). The ESC includes a substrate support including a first segment and a second segment that is laterally adjacent to the first segment. The first segment includes a first pair of electrodes. The second segment includes a second pair of electrodes. The first segment is to be displaced vertically relative to the second segment to accommodate a non-planar surface of a substrate.

### CROSS-REFERENCE TO RELATED APPLICATIONS

This Application claims the benefit of U.S. Provisional Application 63/559,056 filed on Feb. 28, 2024, and entitled “Electrostatic Chuck For Non-Planar Substrates,” the contents of which are incorporated herein by reference.

### BACKGROUND

### Field

Embodiments described herein generally relate to a system and methods used in semiconductor device manufacturing. More specifically, embodiments of the present disclosure relate to an electrostatic chuck (ESC) for use with substrates having non-planar surfaces.

### Description of the Related Art

An electrostatic chuck (ESC) is device used in semiconductor manufacturing to support and retain a substrate while the substrate is being processed. In order to support and retain the substrate, a DC bias is applied to pairs of electrodes disposed within the ESC. The applied DC bias generates an electrostatic force that attracts the substrate to a surface of the ESC. If the substrate is in close enough proximity to the surface of the ESC, then maintaining the applied DC bias (and the electrostatic force) may support and retain the substrate on the surface. By increasing the DC bias, the substrate can be urged towards the surface of the ESC even when portions of the substrate and the surface are initially separated by a small distance (e.g., one millimeter).

However, if portions of the substrate and the surface of the ESC are initially separated by a sufficiently large distance, then increasing the DC bias is generally unable to generate enough electrostatic force to attract the substrate to the surface of the ESC. When a particular substrate is warped or bowed in higher order mode shapes, it is possible for some portions of the particular substrate to be excessively separated from the surface of the ESC while other portions of the particular substrate are contacting the surface of the ESC. In these scenarios, using conventional chucking processes, the substrate must first be flattened (e.g., using a vacuum) before the particular substrate can be attracted to the surface of the ESC. However, flattening the substrate is an inefficient process and could result in damage to the substrate.

Accordingly, there is a need in the art for an ESC that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide an electrostatic chuck (ESC) which includes a substrate support. A first segment of the substrate support includes a first pair of electrodes and the first segment is coupled to a first portion of a membrane. A second segment of the substrate support includes a second pair of electrodes and the second segment is coupled to a second portion of the membrane. The second pair of electrodes is configured to be positioned in a first direction relative to the first pair of electrodes and the first pair of electrodes is configured to be positioned in the first direction relative to the second pair of electrodes. A third segment of the substrate support includes a third pair of electrodes and the third segment is coupled to a third portion of the membrane. The third pair of electrodes is configured to be positioned in the first direction relative to the first pair of electrodes and the second pair of electrodes.

Embodiments of the present disclosure provide a method for chucking a substrate to a substrate support. The method generally includes detecting a first maximum distance between a surface of a first segment of the substrate support and a first portion of the substrate and detecting a second maximum distance between a surface of a second segment of the substrate support and a second portion of the substrate. A first pair of electrodes included in the first segment is actuated a first distance towards the first portion of the substrate. The first distance is less than the first maximum distance. A second pair of electrodes included in the second segment is actuated a second distance towards the second portion of the substrate. The second distance is less than the second maximum distance. A DC bias is applied to the first pair of electrodes and the second pair of electrodes.

Some embodiments disclosed herein are directed to an ESC that includes a substrate support including a first segment and a second segment that is laterally adjacent to the first segment. The first segment includes a first pair of electrodes. The second segment includes a second pair of electrodes. The first segment is configured to be displaced vertically relative to the second segment to accommodate a non-planar surface of a substrate.

Some embodiments disclosed herein are directed to a method for chucking a substrate to a substrate support. The method includes determining a first distance between a surface of a first segment of the substrate support and a first portion of the substrate and determining a second distance between a surface of a second segment of the substrate support and a second portion of the substrate. In addition, the method includes actuating the first segment toward the first portion of the substrate to reduce the first distance and actuating the second segment toward the second portion of the substrate to reduce the second distance. Further, the method includes) applying a DC bias to a first pair of electrodes included in the first segment and to a second pair of electrodes included in the second segment to chuck the first and second portions of the substrate to the first and second segments, respectively.

Some embodiments disclosed herein are directed to an ESC that includes a substrate support including a first segment and a second segment that is laterally adjacent to the first segment. In addition, the ESC includes a first actuator coupled to the first segment that is configured to vertically displace the first segment to reduce a distance between the first segment and a surface of a substrate and a second actuator coupled to the second segment that is configured to vertically displace the second segment to reduce a distance between the second segment and the surface of the substrate. Further, the ESC includes a first pair of electrodes coupled to the first segment that, when energized, are configured to generate a first electrostatic force to urge the substrate toward the first segment and a second pair of electrodes coupled to the second segment that, when energized, are configured to generate a second electrostatic force to urge the substrate toward the second segment.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example substrate processing system, in accordance with certain embodiments of the present disclosure.

FIG. 1B illustrates an example of actuating a segment of a substrate support in a first direction, in accordance with certain embodiments of the present disclosure.

FIG. 1C illustrates an example of actuating a segment of a substrate support in a second direction, in accordance with certain embodiments of the present disclosure.

FIG. 1D illustrates an example of actuating a segment of a substrate support in a third direction, in accordance with certain embodiments of the present disclosure.

FIG. 2 illustrates a representation of example arrangements of segments of a substrate support, in accordance with certain embodiments of the present disclosure.

FIGS. 3A and 3B illustrate examples of layers of a diaphragm disposed over segments of a substrate support, in accordance with certain embodiments of the present disclosure.

FIGS. 4A, 4B, and 4C illustrate representations of chucking a concave substrate, in accordance with certain embodiments of the present disclosure.

FIGS. 5A, 5B, and 5C illustrate representations of chucking a convex substrate, in accordance with certain embodiments of the present disclosure.

FIGS. 6A, 6B, and 6C illustrate examples of a membrane disposed below segments of a substrate support, in accordance with certain embodiments of the present disclosure.

FIGS. 7A and 7B illustrate examples of an electrostatic chuck (ESC) including two segments, in accordance with certain embodiments of the present disclosure.

FIGS. 8A and 8B illustrate examples of an ESC including five segments, in accordance with certain embodiments of the present disclosure.

FIGS. 9A and 9B illustrate examples of an ESC including eight segments, in accordance with certain embodiments of the present disclosure.

FIG. 10 is a flow diagram illustrating a method for substrate processing by chucking a substrate to a substrate support, in accordance with certain embodiments of the present disclosure.

To facilitate understanding, the same reference numerals have been used, where possible, to designate shared elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for substrate processing. More specifically, embodiments described herein provide for an electrostatic chuck (ESC) for electrostatically chucking deformed or otherwise non-planar substrates to a substrate support surface of the ESC. In some embodiments, a first distance is detected between a surface of a first segment of the substrate support and first portion of a substrate, and a second distance is detected between a surface of a second segment of the substrate support and a second portion of the substrate.

In one or more embodiments, the substrate is deformed (e.g., bowed) such that portions of the substrate are different distances from the substrate support. In some examples, the first and second distances are too far from the substrate support to attract and immobilize the substrate on the substrate support by generating an electrostatic force. In various embodiments, a first actuator actuates a first pair of electrodes included in the first segment towards the first portion of the substrate to reduce the first distance between the surface of the first segment and the first portion of the substrate. In one or more examples, a second actuator actuates a second pair of electrodes included in the second segment towards the second portion of the substrate to reduce the second distance between the surface of the second segment and the second portion of the substrate.

In some embodiments, a DC bias is applied to the first pair of electrodes and the second pair of electrodes. In various examples, the DC bias generates electrostatic forces which attract the first portion of the substrate to the surface of the first segment and also attract the second portion of the substrate to the surface of the second segment. By actuating and adjusting the distance between the first and second pairs of electrodes and the substrate, the substrate can be chucked to the surface of the ESC without first flattening the substrate as often performed during conventional chucking processes. This increases efficiency of processing the substrate and may avoid the risk of damaging the substrate (e.g., during a flattening process).

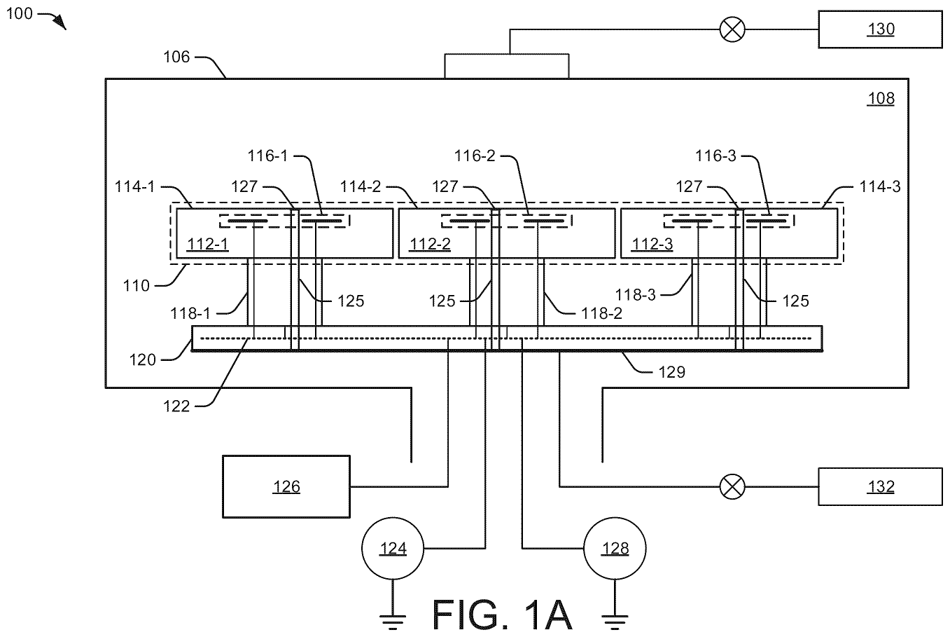

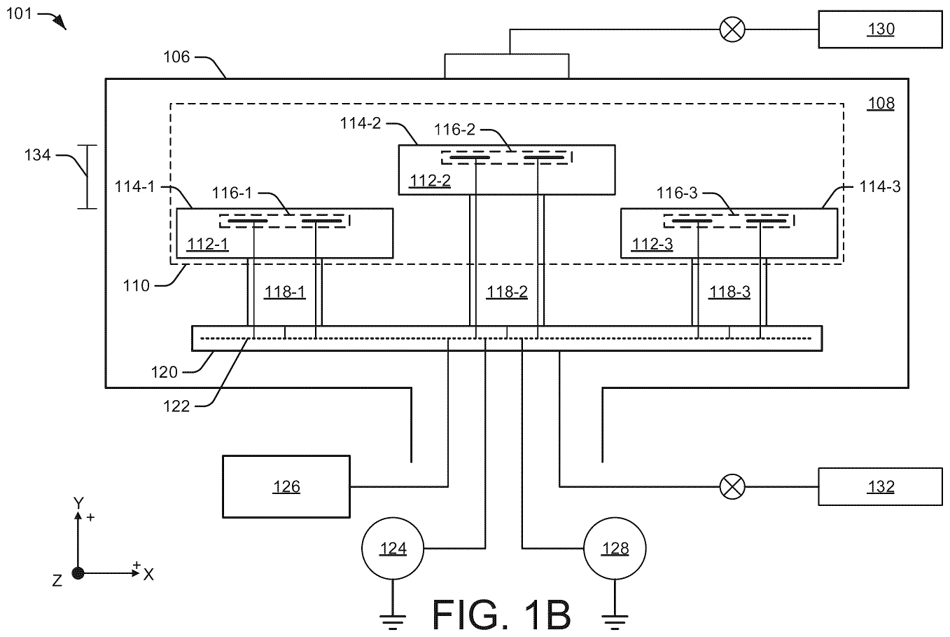

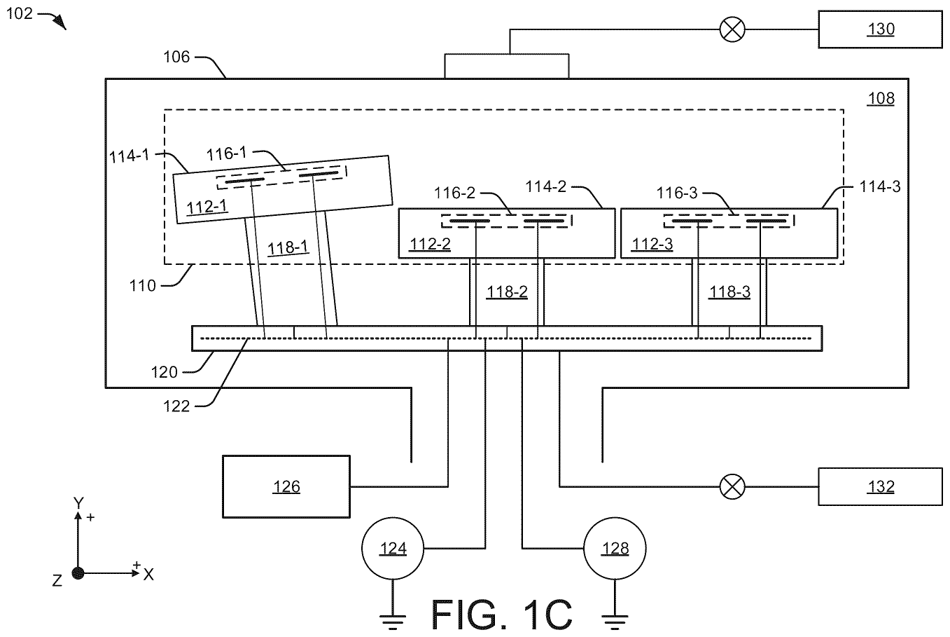

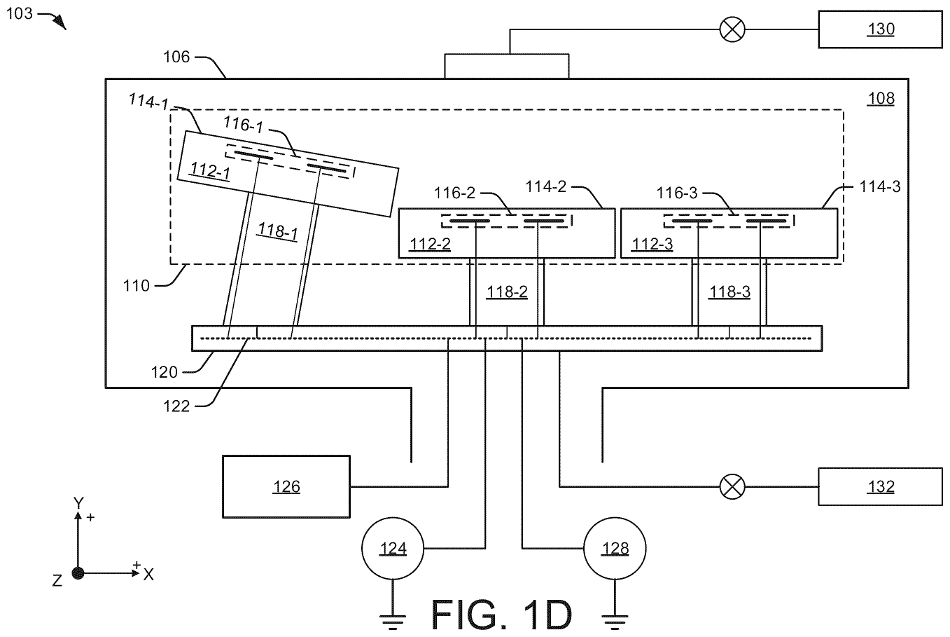

FIG. 1A is a schematic representation of an example substrate processing system 100. The substrate processing system 100 is representative of a variety of different systems including, without limitation, chemical vapor deposition (CVD) systems, plasma vapor deposition (PVD) systems, etching systems (including plasma-assisted systems and non-plasma-assisted systems), electron beam systems, etc. The substrate processing system 100 is illustrated to include a processing chamber 106 which contains a processing volume 108.

As shown in FIG. 1A, a substrate support 110 of an electrostatic chuck (ESC) is disposed within the processing volume 108. The substrate support 110 is illustrated to include segments 112-1, 112-2, 112-3. The segment 112-1 is adjacent (such as laterally adjacent) to the segment 112-2, and the segment 112-2 is adjacent (such as laterally adjacent) to the segment 112-3. For instance, the segment 112-1 has a surface 114-1 (such as a top surface). A pair of electrodes 116-1 is disposed within the segment 112-1 below the surface 114-1. The segment 112-1 is coupled to an actuator 118-1 which is configured to actuate the segment 112-1 within the processing volume 108. The actuator 118-1 is representative of a variety of different types of actuators capable of adjusting the position of the segment 112-1. In various embodiments, the actuator 118-1 may be electrical (e.g., includes a solenoid actuator, a DC motor, a stepper motor, a linear motor, etc.), hydraulic, electrohydraulic, pneumatic, piezoelectric, magnetostrictive, and/or any other type of actuator. In some examples, the actuator 118-1 includes a membrane (e.g., thin metal or polymer disk) that encloses a pressurizable region formed within the substrate support 110 that is configured to cause movement (e.g., deformation) of a surface of the membrane due to the adjustment of a fluid pressure or application of a vacuum pressure applied to the pressurizable region. In some examples, the actuator 118-1 includes a piezoelectric actuator or solenoid type actuator that is configured to adjust the position of the segment 112-1, 112-2, or 112-3 that it is coupled to during processing.

Like the segment 112-1, the segment 112-2 has a surface 114-2 (such as a top surface) and a pair of electrodes 116-2 disposed below the surface 114-2. The segment 112-3 also has a surface 114-3 (such as a top surface) and a pair of electrodes 116-3 disposed below the surface 114-3. The segment 112-2 is coupled to an actuator 118-2 which is configured to actuate the segment 112-2 within the processing volume 108. In some examples, the actuator 118-2 is a same type of actuator as the actuator 118-1. In other examples, the actuator 118-2 can be a different type of actuator than the actuator 118-1. Similarly, the segment 112-3 is also coupled to an actuator 118-3 that is configured to actuate the segment 112-3 within the processing volume 108.

In some embodiments, a printed circuit board (PCB) 120 is disposed below the segments 112-1, 112-2, 112-3. In other embodiments, the PCB 120 may be disposed in different orientations relative to the segments 112-1, 112-2, 112-3. In the illustrated example, the pairs of electrodes 116-1, 116-2, 116-3 are electrically connected to a circuit layer 122 of the PCB 120, and the electrical components (e.g., electrical actuators (e.g., solenoid, piezoelectric device), switches, fluid valves, etc.) of the actuators 118-1, 118-2, 118-3 used to cause an actuating motion are electrically connected to the circuit layer 122. A DC voltage source 124 is also illustrated to be electrically connected to the circuit layer 122 of the PCB 120. In various embodiments, the DC voltage source 124 is capable of outputting example voltages of ±5000 V, ±10,000 V, ±20,000 V, etc. that can be applied to the pairs of electrodes 116-1, 116-2, 116-3 to generate a bias that is able to generate a chucking force on a substrate disposed over the surfaces 114-1, 114-2, and 114-3.

The substrate processing system 100 is illustrated to include a controller 126 which is communicatively coupled (e.g., electrically connected) to the circuit layer 122 of the PCB 120. In some embodiments, the controller 126 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 126 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

The PCB 120 (e.g., the circuit layer 122) includes multiple transistors (e.g., MOSFETs) configured as switches. In some embodiments, the controller 126 is capable of controlling the transistors included in the PCB 120 to open or close electrical connections between the DC voltage source 124 and the pairs of electrodes 116-1, 116-2, 116-3. Similarly, in some embodiments, the controller 126 is capable of controlling the transistors included in the PCB 120 to open or close electrical connections between a power supply 128 and the actuators 118-1, 118-2, 118-3 to selectively power the electrical components used to cause the movement and positioning of the segments 112-1, 112-2, 112-3 by the actuators 118-1, 118-2, 118-3. In various embodiments, the power supply 128 can be an AC power supply, a DC power supply, or representative of an AC power supply and a DC power supply.

In some examples, the one or more processors of the controller 126 execute instructions which cause the one or more processors to control the transistors in the circuit layer 122 and close electrical connections between the DC voltage source 124 and the pair of electrodes 116-1, the pair of electrodes 116-2, and/or the pair of electrodes 116-3. In these examples, closing the electrical connections applies a DC bias to the pair of electrodes 116-1, the pair of electrodes 116-2, and/or the pair of electrodes 116-3. For example, if the DC bias is applied to the pair of electrodes 116-1, then the DC bias generates an electrostatic force that acts on the portion of the substrate disposed over the surface 114-1. While not intending to be bound by theory, generated electrostatic forces are typically capable of attracting a portion of a substrate to the surface 114-1 if the portion of the substrate is a relatively small distance (e.g., one millimeter) from the pair of electrodes 116-1. In one non-limiting example, when a bias voltage of about 1 kV for a Johnsen-Rahbek ESC and about 3 kV for a Coulombic ESC is applied between a pair of electrodes the applied bias is able to cause movement in a portion of a deformed silicon substrate that is spaced about one millimeter from the surface 114-1 of the electrostatic chuck.

If the portion of the substrate is spaced too far from the pair of electrodes 116-1, then the electrostatic force generated by the DC bias is insufficient to attract the portion of the substrate to the surface 114-1. In order to decrease the distance between the pair of electrodes 116-1 and the portion of the substrate, the one or more processors of the controller 126 execute instructions that cause the one or more processors to control the transistors in the circuit layer 122 and close an electrical connection between the power supply 128 and the actuator 118-1. Supplying power from the power supply 128 to the actuator 118-1 causes the actuator 118-1 to actuate the segment 112-1 relative to the position of the portion of the substrate. In some examples, actuating the segment 112-1 relative to the portion of the substrate decreases the distance between the pair of electrodes 116-1 and the portion of the deformed substrate until the electrostatic force is sufficient to attract the portion of the substrate to the surface 114-1 of the segment 112-1.

Thus, in some embodiments, each of the segments 112-1, 112-2, 112-3 are configured to be displaced (e.g., via actuators 118-1, 118-2, 118-3) relative to the other segments. As will be described in more detail herein, in some embodiments, one or more of the segments 112-1, 112-2, 112-3 may be configured to be displaced vertically (e.g., the Z direction) and possibly also laterally (e.g., in the X-Y plane) relative to the other segments.

As shown in FIG. 1A, the substrate processing system 100 includes a gas delivery system 130, and the gas delivery system 130 is coupled to the processing volume 108. The gas delivery system 130 is configured to deliver at least one processing gas (e.g., argon, nitrogen, oxygen, hydrogen, etc.) to the processing volume 108. In examples in which the substrate processing system 100 includes a plasma-assisted system, the processing gas can include at least one of an inert gas (e.g., helium, argon, nitrogen (N₂)) or dry etching gas (e.g., HBr, HF, HCl, CF₄, NF₃ or XeF₂). In some embodiments, the gas delivery system 130 can include components for activating or energizing one or more processing gasses before delivering the processing gasses to the processing volume 108. The substrate processing system 100 is also illustrated to include a vacuum source 132 in communication with the processing volume 108.

In some embodiments of the substrate support 110, the segments 112-1, 112-2, and 112-3 each further include one or more vacuum chucking ports 125 that include an opening 127 that is formed through the surface 114-1, 114-2, and 114-3. The openings 127 of the vacuum chucking ports 125 are coupled to a line 129 that is coupled to the vacuum source 132 through a controlling valve (not shown) to selectively generate a vacuum pressure at the surfaces 114-1, 114-2, and 114-3 of each of the segments 112-1, 112-2, and 112-3 by use of commands from the controller 126. In some embodiments, a vacuum pressure from the vacuum source 132 may be utilized to help flatten a substrate by vacuum chucking the substrate, and/or dechuck the substrate. The one or more vacuum chucking ports 125 can also be used as backside gas delivery ports through which an inert gas is delivered during processing.

FIG. 1B illustrates an example 101 of actuating a segment of a substrate support in a first direction. In some embodiments, the one or more processors of the controller 126 execute instructions which cause the one or more processors to control the transistors in the circuit layer 122 and close an electrical connection between the power supply 128 and the actuator 118-2. As shown, supplying power from the power supply 128 to the actuator 118-2 causes the actuator 118-2 to actuate (e.g., position) the segment 112-2 in a first direction which is normal to the PCB 120. The first direction is in a first plane (that extends in the positive Y direction) within the processing volume 108, and the segment 112-2 is illustrated to be positioned in the first direction. In some embodiments, the segment 112-2 can actuate independently of the segment 112-1 and the segment 112-3 such that the surface 114-2 extends a distance 134 from the surface 114-1 and the surface 114-3. For example, actuating and translating the segment 112-2 in the first direction may facilitate chucking of a bowed substrate (e.g., backside surface of the substrate is concave) which contacts the surface 114-1 and the surface 114-3 and that extends a distance greater than the relatively small distance from the surface 114-2.

FIG. 1C illustrates an example 102 of actuating a segment of a substrate support in a second direction. In various embodiments, the one or more processors of the controller 126 execute instructions which cause the one or more processors to control the transistors in the circuit layer 122 and close an electrical connection between the power supply 128 and the actuator 118-1. As shown, supplying power from the power supply 128 to the actuator 118-1 causes the actuator 118-1 to actuate (e.g., position) the segment 112-1 in a second direction which is at a first slight angle relative to the PCB 120. The angle shown in FIG. 1C has been exaggerated for ease of illustration. The second direction is in a second plane (that extends in both the positive Y direction and the negative X direction) within the processing volume 108. Thus, actuation of segment 112-1 in the second direction may translate the segment 112-1 both vertically and laterally within the processing volume 108 relative to the other segments 112-2, 112-3. Specifically, in the example illustrated in FIG. 1C, the segment 112-1 may be translated both vertically and laterally away from the other segments 112-2, 112-3 within the processing volume 108. In some examples, actuating and translating the segment 112-1 in the second direction may facilitate chucking of a bowed substrate which does not contact any of the surfaces 114-1, 114-2, 114-3. The angle of the second direction relative to the first direction can be fixed or adjusted by orienting the displacement direction of the actuator 118-1 based on prior testing or modeling of the bow of a substrate that is commonly provided to the processing chamber 106. In various embodiments, the segment 112-1 (and the pair of electrodes 116-1) may also be positioned in the first direction in which the segment 112-2 is positioned as shown in FIG. 1B. In some embodiments, a process of positioning the segment 112-1 (and the pair of electrodes 116-1) a distance in the first direction includes translating the segment 112-1 (and the pair of electrodes 116-1) a distance in the second direction.

FIG. 1D is illustrates an example 103 of actuating a segment of a substrate support in a third direction. In certain embodiments, the one or more processors of the controller 126 execute instructions which cause the one or more processors to control the transistors in the circuit layer 122 and close an electrical connection between the power supply 128 and the actuator 118-1. As shown, supplying power from the power supply 128 to the actuator 118-1 causes the actuator 118-1 to actuate (e.g., position) the segment 112-1 in a third direction which is at a second slight angle relative to the PCB 120. The angle shown in FIG. 1D has been exaggerated for ease of illustration. The third direction is in a third plane (that extends in both the positive Y direction and the positive X direction) within the processing volume 108. Thus, actuation of segment 112-1 in the third direction may translate the segment 112-1 both vertically and laterally within the processing volume 108 relative to the other segments 112-2, 112-3. Specifically, in the example illustrated in FIG. 1D, the segment 112-1 may be translated both vertically and laterally toward from the other segments 112-2, 112-3 within the processing volume 108. For example, actuating and translating the segment 112-1 in the third direction may facilitate chucking of a bowed substrate that contacts the surface 114-2 but does not contact the surface 114-1 or the surface 114-3. The angle of the third direction relative to the first direction can be fixed or adjusted by orienting the displacement direction of the actuator 118-1 based on prior testing or modeling of the bow of a substrate that is commonly provided to the processing chamber 106. In some embodiments, the segment 112-1 (and the pair of electrodes 116-1) may also be positioned in the first direction in which the segment 112-2 is positioned as shown in FIG. 1B. In one or more embodiments, a process of positioning the segment 112-1 (and the pair of electrodes 116-1) a distance in the first direction includes translating the segment 112-1 (and the pair of electrodes 116-1) a distance in the third direction.

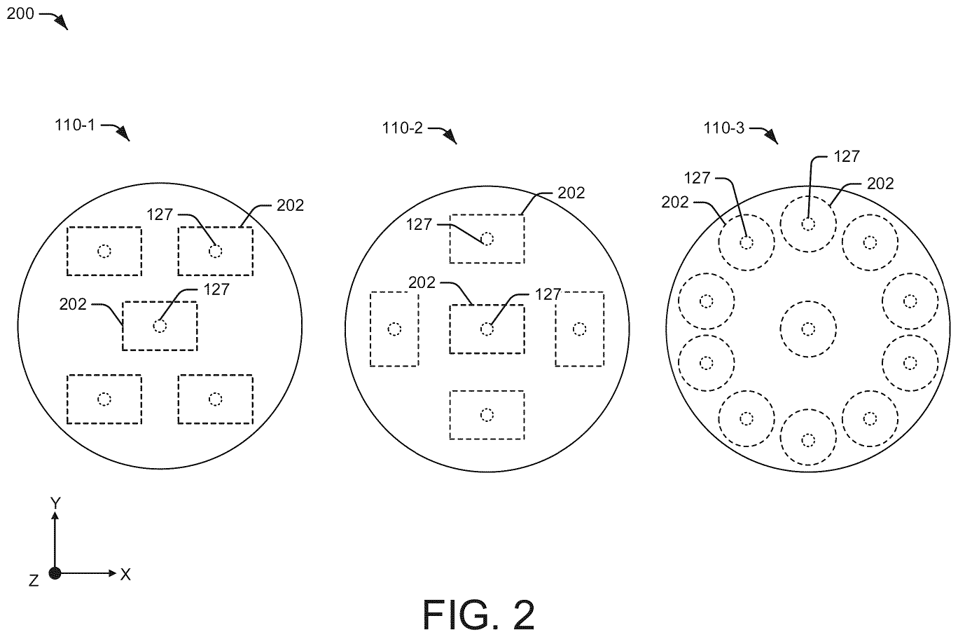

FIG. 2 illustrates a representation 200 of example arrangements of segments (e.g., segments 112) of a substrate support, in accordance with certain embodiments of the present disclosure. In a first example 110-1, segments 202 of the substrate support 110 are rectangular in shape and arranged in a set of five segments 202 with a central segment 202 and four segments 202 surrounding the central segment 202. Similarly, in a second example 110-2, segments 202 of the substrate support 110 are rectangular in shape and arranged in a set of five segment 202 with a central segment 202 and four segments 202 surrounding the central segment 202. In a third example 110-3, segments 202 of the substrate support 110 are circular in shape and arranged in a set of 11 segments 202 with one centered segment 202 encircled by 10 additional segments 202. It is to be appreciated that the segments 202 of the substrate support 110 may be arranged in a variety of different arrangements and that the examples 110-1, 110-2, 110-3 are non-limiting examples. In some embodiments, each of the segments 220 illustrated in the examples are configured to be actuated in a direction that primarily extends in and out of the page (e.g., the Z or vertical direction) of FIG. 2.

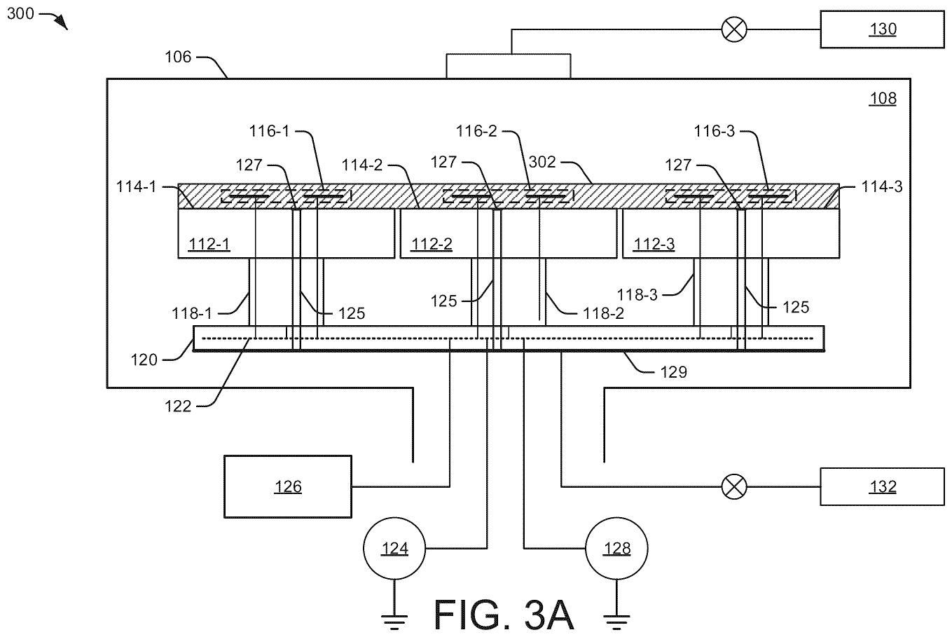

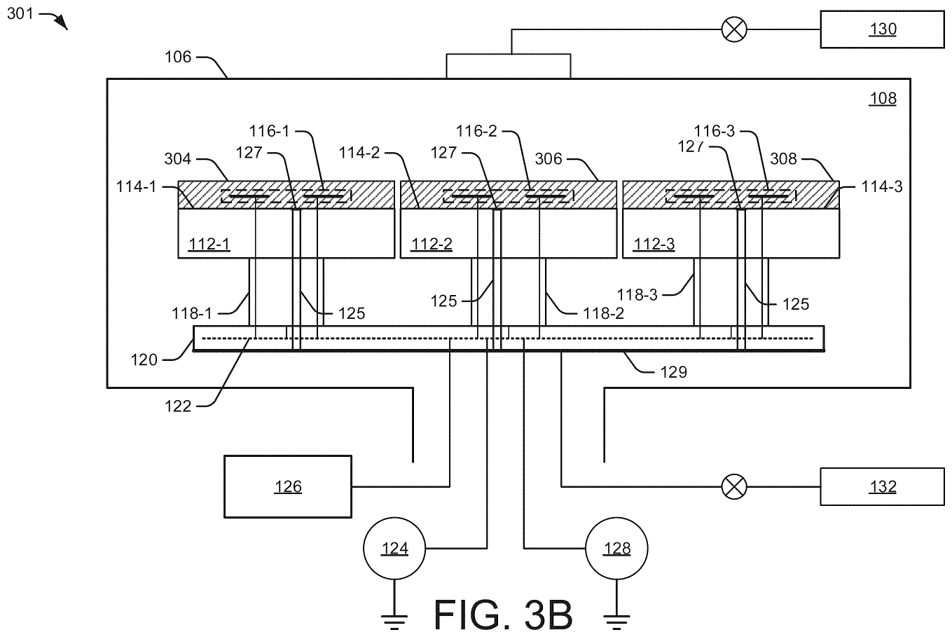

FIGS. 3A and 3B illustrates example top layers that may be disposed over segments of a substrate support. In FIG. 3A, an example 300 of top layer is shown that comprises a diaphragm 302 constructed from a single layer of the fluoroelastomer, polyimide, or other compliant material disposed over each of the surfaces 114-1, 114-2, 114-3. As shown, in some embodiments, the pairs of electrodes 116-1, 116-2, 116-3 may be disposed in the diaphragm 302. In certain embodiments, the segments 112-1, 112-2, 112-3 may include multiple alternative electrical connections with the circuit layer 122, and the diaphragm 302 can have different pairs of electrodes connected to the multiple alternative electrical connections that are oriented differently than the pairs of electrodes 116-1, 116-2, 116-3.

In some embodiments, the fluoroelastomer material of the diaphragm 302 includes a perfluoroelastomer material. In certain embodiments, the diaphragm 302 covers openings between the segments 112-1, 112-2, 112-3 to avoid discontinuities between a portion of a substrate and the diaphragm 302. In examples in which the fluoroelastomer material of the diaphragm 302 includes the perfluoroelastomer material, the diaphragm 302 is fluorine resistant and also protects the segments 112-1, 112-2, 112-3 from a variety of corrosive agents which may be utilized within the processing volume 108. In some embodiments, the diaphragm 302 may be actuated using the vacuum source 132 through a controlling valve (not shown) to selectively generate a vacuum pressure at the surfaces 114-1, 114-2, and 114-3 of each of the segments 112-1, 112-2, and 112-3 by use of commands from the controller 126. In one or more examples, the vacuum chucking ports 125 may direct the selectively generated vacuum pressure to cause the diaphragm 302 to actuate away from the surfaces 114-1, 114-2, and 114-3 or towards the surfaces 114-1, 114-2, and 114-3. In various embodiments, actuating the diaphragm 302 may be configured to manipulate the portion of the substrate, for example, by causing the portion of the substrate to actuate closer to at least one of the surfaces 114-1, 114-2, 114-3.

In FIG. 3B, an example 301 of multiple top layers 304, 306, 308 disposed over the surfaces 114-1, 114-2, 114-3 of segments 112-1, 112-2, 112-3, respectively, is shown. In some embodiments, the top layers 304, 306, 308 may comprise the same material(s) as the diaphragm 302 in FIG. 3A (e.g., a fluoroelastomer, polyimide, or other compliant material). More specifically, in various embodiments, the top layer 304 is disposed over the surface 114-1; the top layer 306 is disposed over the surface 114-2; and the top layer 308 is disposed over the surface 114-3. In some embodiments, the pair of electrodes 116-1 is disposed in the layer 304; the pair of electrodes 116-2 is disposed in the layer 306; and the pair of electrodes 116-3 is disposed in the layer 308. In one or more embodiments, the fluoroelastomer material includes a perfluoroelastomer material which is configured to be resistant to extreme temperatures, fluorine, and corrosive chemistries. In some examples, the layers 304, 306, 308 are flexible and capable of mechanically deforming in order to chuck bowed or otherwise non-planar surfaces or portions of substrates.

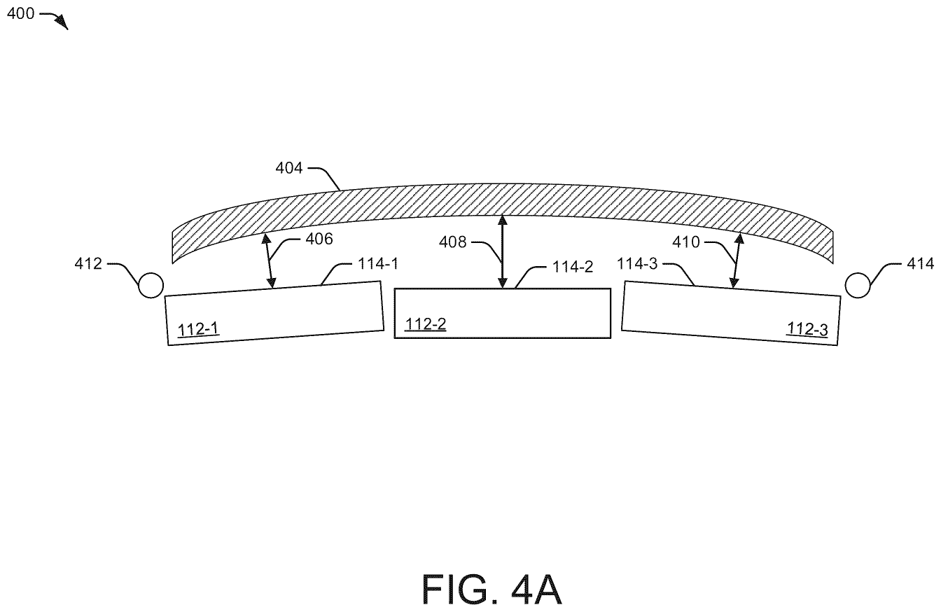

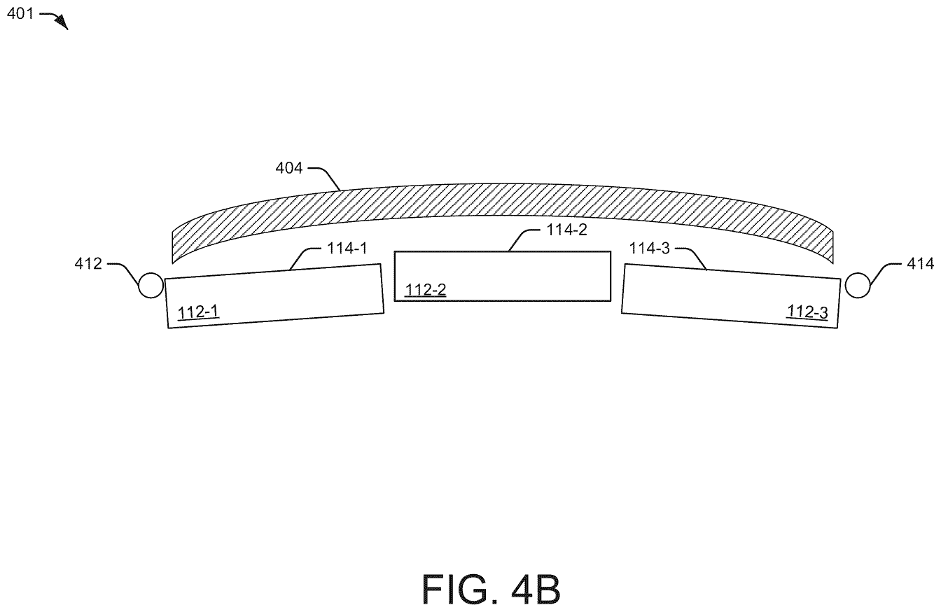

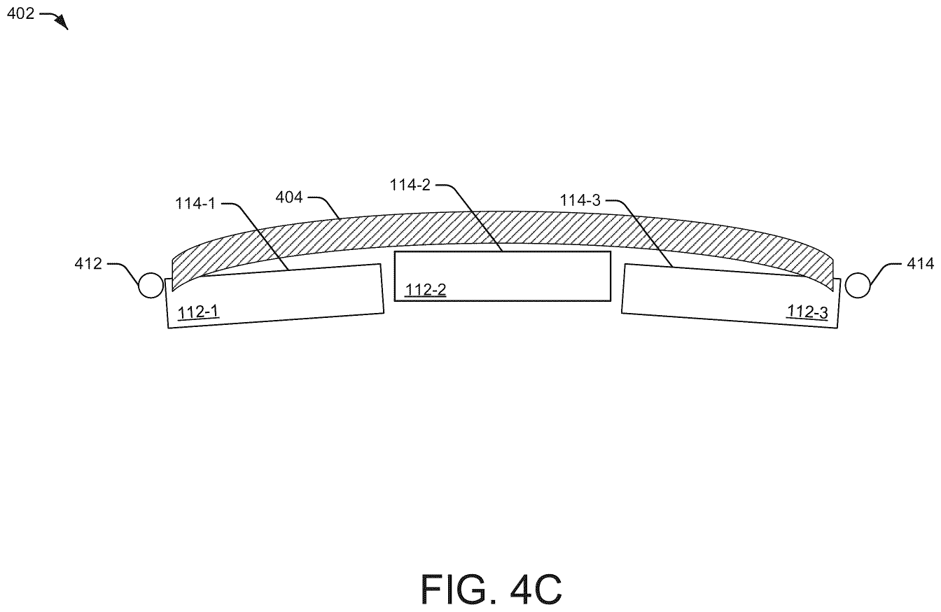

FIGS. 4A, 4B, and 4C illustrate representations of chucking a concave substrate (or a substrate having a concave surface), in accordance with certain embodiments of the present disclosure. FIG. 4A illustrates a representation 400 of detecting distances between a surface of an electrostatic chuck (ESC) and a concave substrate 404 and/or detecting the deformed shape of the concave substrate 404. The representation 400 includes the segments 112-1, 112-2, 112-3. As shown, the representation 400 also includes indications of a distance 406 (such as a maximum distance or an average distance in some embodiments) between the surface 114-1 and a first portion (e.g., first edge portion) of the concave substrate 404, a distance 408 (such as a maximum distance or an average distance in some embodiments) between the surface 114-2 and a second portion (e.g., central portion) of the concave substrate 404, and a distance 410 (such as a maximum distance or an average distance in some embodiments) between the surface 114-3 and a third portion (e.g., second edge portion) of the concave substrate 404.

In one or more embodiments, the distance 406 is a distance that is greater than a distance at which applying a DC bias to the pair of electrodes 116-1 generates an electrostatic force capable of attracting the first portion of the concave substrate 404 to the surface 114-1. In various examples, the distance 406 may be greater than 1.0 millimeter such as 1.25 millimeters, 1.5 millimeters, 1.75 millimeters, 2.0 millimeters, etc. In some examples, the distance 406 may be a distance in a range of 1.0 to 10.0 millimeters. In certain embodiments, the distance 406 may be greater than 10.0 millimeters. In various embodiments, the distance 406 may be a percentage of a length, width, or diameter of the concave substrate 404 such as a percentage in a range of 0.33 to 3.33 percent of the length, width, or diameter of the concave substrate 404.

In some embodiments, the distances 406, 408, 410 are detected by sensors 412, 414 disposed in the processing volume 108. The sensors 412, 414 are representative of a variety of different types and/or combinations of types of sensors which are capable of detecting the maximum distances 406, 408, 410. In some embodiments, one or more sensors 412, 414 are disposed in each of the segments 112-1, 112-2, 112-3. The controller 126 is configured to receive the detected distances 406, 408, 410 and then adjust the displacement (such as the vertical displacement and/or lateral displacement) of the segments 112-1, 112-2, 112-3 by use of the actuators 118-1, 118-2, 118-3 to compensate for the detected distortion of the concave substrate 404. In various embodiments, the sensors 412, 414 can be capacitive sensors that detect the distances 406, 408, 410 based on changes in capacitance caused by increasing or decreasing the distance between the concave substrate 404 and the surfaces 114-1, 114-2, 114-3. In certain embodiments, the sensors 412, 414 may be eddy current sensors that detect the distances 406, 408, 410 based on electromagnetic induction. For example, increasing or decreasing the distance between the concave substrate 404 and the surfaces 114-1, 114-2, 114-3 affects eddy currents induced in the sensors 412, 414 enabling detection of the distances 406, 408, 410. In one or more embodiments, the sensors 412, 414 may leverage electromagnetic induction as inductive sensors that measure changes in inductance caused by increasing or decreasing the distance between the concave substrate 404 and the surfaces 114-1, 114-2, 114-3 to detect the distances 406, 408, 410. In various embodiments, the sensors 412, 414 can be optical sensors (e.g., laser, infrared, etc.) which utilize light reflection or interference in order to detect the distances 406, 408, 410. In some examples, the sensors 412, 414 are ultrasonic sensors which transmit ultrasonic waves and receive reflected ultrasonic waves. In these examples, the sensors 412, 414 detect the distances 406, 408, 410 based on an amount of time between transmitting the ultrasonic waves and receiving the reflected ultrasonic waves. In certain embodiments, the sensors 412, 414 may be piezoelectric sensors that generate a voltage in response to a mechanical stress, and then detect the distances 406, 408, 410 by measuring the generated voltage. Although particular examples of the sensors 412, 414 have been described, it is to be appreciated that the sensors 412, 414 are not limited to these examples and may be any sensors capable of detecting the distances 406, 408, 410.

In some alternate embodiments, the distances 406, 408, 410 can be detected by a substrate bow measurement system (not shown) disposed in a chamber that is within a system that includes the processing volume 108 such that the detected substrate bow can be provided to the controller 126 so that the displacement of the segments 112-1, 112-2, 112-3 by the actuators 118-1, 118-2, 118-3 can be set to compensate to the detected distortion of the concave substrate 404. In some embodiments, the distances 406, 408, 410 are described by premeasured bow information measured for the concave substrate 404. In various embodiments, the premeasured bow information can be measured by the substrate bow measurement system and/or the sensors 412, 414. In some embodiments, the premeasured bow information for the concave substrate 404 may also be utilized to dechuck the concave substrate 404.

FIG. 4B illustrates a representation 401 of decreasing the distances between the surface of the ESC and the concave substrate 404. In some embodiments, the one or more processors of the controller 126 execute instructions which cause the one or more processors to control the transistors in the circuit layer 122 and close electrical connections between the power supply 128 and the actuators 118-1, 118-2, 118-3. Supplying power to electrical components of the actuators 118-1, 118-2, 118-3 from the power supply 128 causes the actuators 118-1, 118-2, 118-3 to actuate the segments 112-1, 112-2, 112-3, respectively, towards the concave substrate 404. As shown in FIG. 4B, the actuator 118-1 actuates the pair of electrodes 116-1 included in the segment 112-1 a first distance towards the first portion (e.g., the first edge portion) of the concave substrate 404. In various embodiments, the first distance is included in or based on the premeasured bow information for the concave substrate 404. In one or more embodiments, the first distance is less than the distance 406 (FIG. 4A). In some examples, after actuating the pair of electrodes 116-1 the first distance, the pair of electrodes 116-1 is close enough to the first portion of the concave substrate 404 that applying a DC bias to the pair of electrodes 116-1 generates an electrostatic force capable of attracting the first portion of the concave substrate 404 to the surface 114-1.

The actuator 118-2 actuates the pair of electrodes 116-2 a second distance towards the second portion (e.g., the central portion) of the concave substrate 404. In some embodiments, the second distance is included in or based on the premeasured bow information for the concave substrate 404. In one or more examples, the second distance is less than the distance 408 (FIG. 4A). The actuator 118-3 actuates the pair of electrodes 116-3 a third distance towards the third portion (e.g., the second edge portion) of the concave substrate 404. In certain embodiments, the third distance is included in or based on the premeasured bow information for the concave substrate 404. In some examples, the third distance is less than the distance 410 (FIG. 4A). Similar to actuating the pair of electrodes 116-1 the first distance, after actuating the pair of electrodes 116-2 the second distance, the pair of electrodes 116-2 is close enough to the second portion of the concave substrate 404 that applying the DC bias to the pair of electrodes 116-2 generates an electrostatic force capable of attracting the second portion of the concave substrate 404 to the surface 114-2. After actuating the pair of electrodes 116-3 the third distance, the pair of electrodes 116-3 is close enough to the third portion of the concave substrate 404 that applying the DC bias to the pair of electrodes 116-3 generates an electrostatic force capable of attracting the third portion of the concave substrate 404 to the surface 114-3.

FIG. 4C illustrates a representation 402 of chucking the concave substrate 404. In some embodiments, the one or more processors of the controller 126 execute instructions which cause the one or more processors to control the transistors in the circuit layer 122 and close electrical connections between the DC voltage source 124 and the pairs of electrodes 116-1, 116-2, 116-3 which applies the DC bias to the pairs of electrodes 116-1, 116-2, 116-3. Electrostatic forces are generated which attract the first portion of the concave substrate 404 to the surface 114-1, the second portion of the concave substrate 404 to the surface 114-2, and the third portion of the concave substrate 404 to the surface 114-3.

After chucking the concave substrate 404, the concave substrate 404 may be flattened using a vacuum pressure from the vacuum source 132 via the vacuum chucking ports 125 and/or by actuating the actuators 118-1, 118-2, 118-3 to flatten the concave substrate 404. In some embodiments, the vacuum pressure is included in or based on the premeasured bow information for the concave substrate 404. In certain embodiments, the concave substrate 404 can be processed with or without flattening the concave substrate 404. In various embodiments, after processing the concave substrate 404, the concave substrate 404 can be dechucked by ceasing application of the DC bias to the pairs of electrodes 116-1, 116-2, 116-3 and/or by actuating the actuators 118-1, 118-2, 118-3 to dechuck the concave substrate 404.

In some embodiments, the concave substrate 404 is dechucked based on the premeasured bow information in order to avoid undesirable movements (e.g., spring-back) of the concave substrate 404 during the dechucking process. In one or more embodiments, ceasing the application of the DC bias to the pairs of electrodes 116-1, 116-2, 116-3 is performed in a particular order (e.g., the DC bias is ceased for the pairs of electrodes 116-1, 116-3 before ceasing the application of the DC bias to the pair of electrodes 116-2) based on the premeasured bow information for the concave substrate 404. In certain embodiments, a manner in which the application of the DC bias to the pairs of electrodes is ceased (e.g., a rate at which the DC bias is reduced) may be based on the premeasured bow information for the concave substrate 404. In some embodiments, distances that the actuators 118-1, 118-2, 118-3 are actuated to dechuck the concave substrate 404 can be based on the premeasured bow information for the concave substrate 404. In certain embodiments, a manner in which the application of the DC bias to the pairs of electrodes is ceased and/or the movement of the pairs of electrodes 116-1, 116-2, 116-3 towards a substrate's original deformed state during a dechucking process may be based on the premeasured bow information or measured bow information for the concave substrate 404.

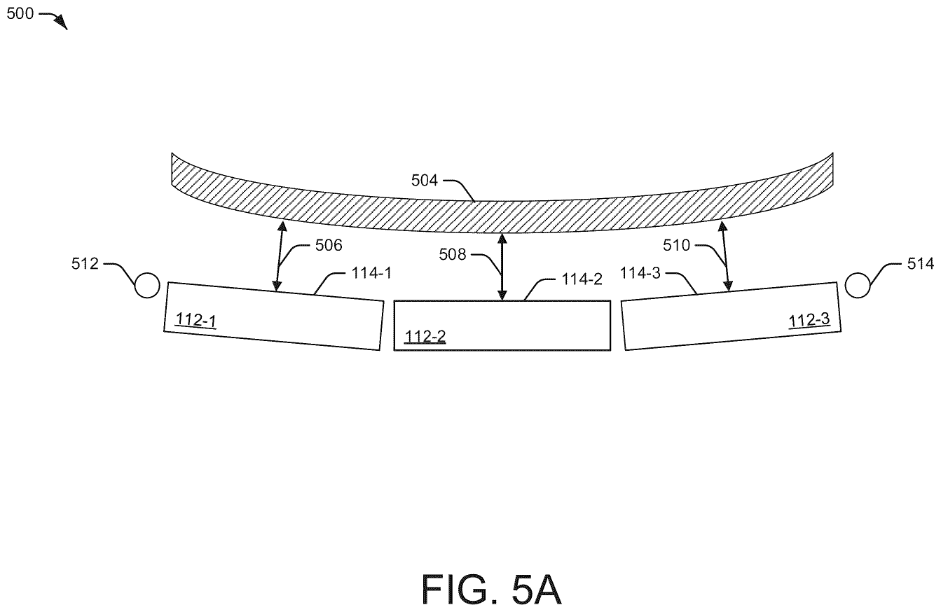

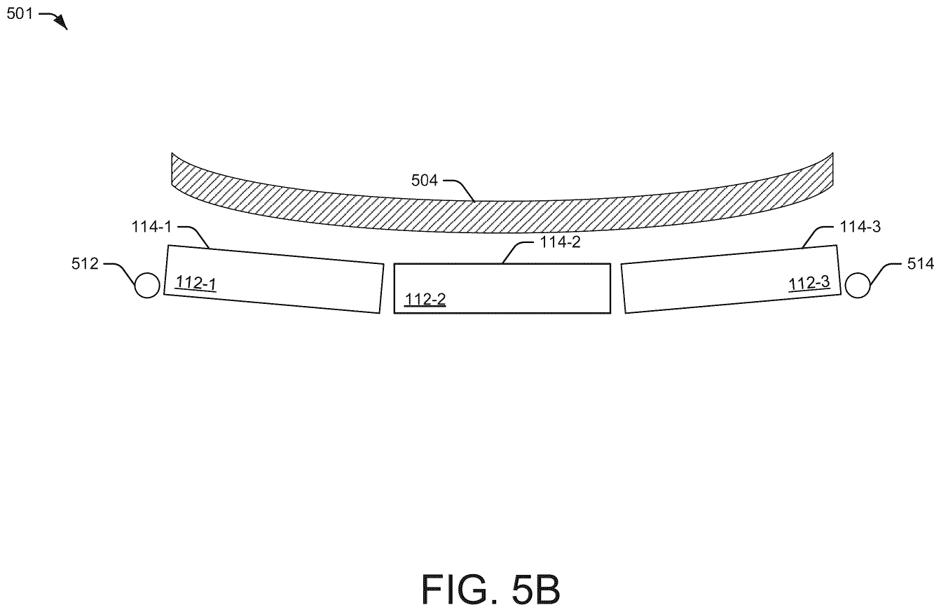

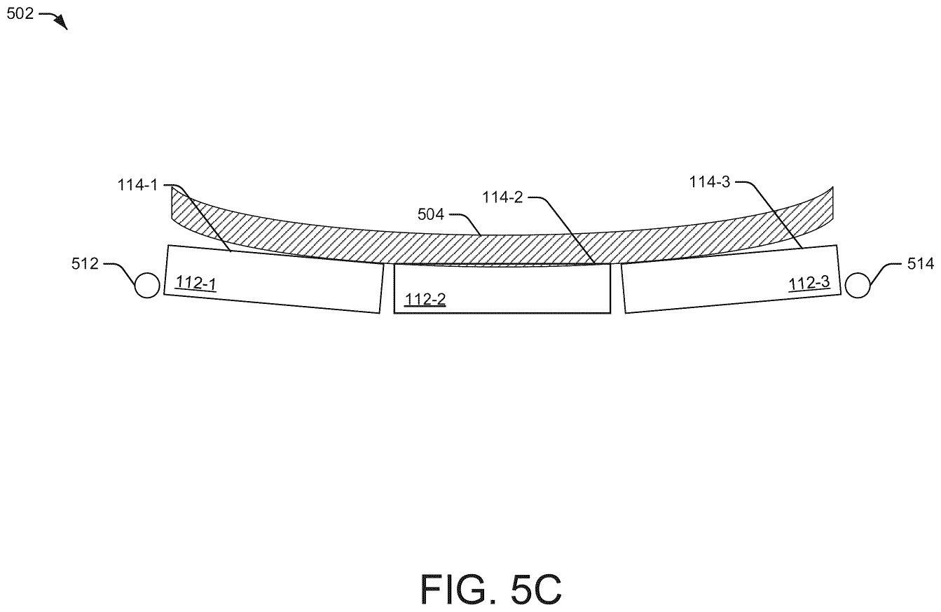

FIGS. 5A, 5B, and 5C illustrate representations of chucking a convex substrate (or a substrate having a convex surface). FIG. 5A illustrates a representation 500 of detecting distances between a surface of an electrostatic chuck (ESC) and a convex substrate 504 (or a substrate having a convex surface) and/or detecting the deformed shape of the convex substrate 504. The representation 500 includes the segments 112-1, 112-2, 112-3 as well as indications of a distance 506 (such as a maximum distance or an average distance in some embodiments) between the surface 114-1 and a first portion (e.g., first edge portion) of the convex substrate 504, a distance 508 (such as a maximum distance or an average distance in some embodiments) between the surface 114-2 and a second portion (e.g., central portion) of the convex substrate 504, and a distance 510 (such as a maximum distance or an average distance in some embodiments) between the surface 114-3 and a third portion (e.g., second edge portion) of the convex substrate 504.

In various embodiments, the distances 506, 508, 510 are detected by sensors 512, 514. In some embodiments, the sensors 512, 514 may be the same sensors as the sensors 412, 414. In other embodiments, the sensors 512, 514 can be different sensors than the sensors 412, 414. In certain embodiments, the distances 506, 508, 510 are greater distances than distances at which electrostatic forces can be generated to attract the first, second, and third portions of the convex substrate 504 to the surfaces 114-1, 114-2, 114-3, respectively. In some embodiments, the distances 506, 508, 510 can be detected by a substrate bow measurement system disposed in a chamber that is within a system that includes the processing volume 108 such that the detected substrate bow can be provided to the controller 126 so that the displacement of the segments 112-1, 112-2, 112-3 (such as the vertical displacement and/or lateral displacement) by the actuators 118-1, 118-2, 118-3 can be set to compensate for the detected distortion of the convex substrate 504. In one or more embodiments, the distances 506, 508, 510 are described by premeasured bow information for the convex substrate 504. In various embodiments, the premeasured bow information can be measured by the substrate bow measurement system and/or the sensors 512, 514. In certain embodiments, the premeasured bow information for the convex substrate 504 may also be utilized to dechuck the convex substrate 504 in the same or similar ways as the premeasured bow information for the concave substrate 404 can be utilized to dechuck the concave substrate 404.

FIG. 5B illustrates a representation 501 of decreasing the distances between the surface of the ESC and the convex substrate 504. In one or more embodiments, the controller 126 causes the actuators 118-1, 118-2, 118-3 to actuate the pairs of electrodes 116-1, 116-2, 116-3 towards the convex substrate 504. In some embodiments, after actuating the pairs of electrodes 116-1, 116-2, 116-3 towards the convex substrate 504, the pairs of electrodes 116-1, 116-2, 116-3 generate electrostatic forces which attract the first, second, and third portions of the convex substrate 504 to the surfaces 114-1, 114-2, 114-3, respectively.

FIG. 5C illustrates a representation 502 of chucking the convex substrate 504. In various embodiments, the controller 126 causes the DC bias to be applied to the pairs of electrodes 116-1, 116-2, 116-3 and electrostatic forces are generated which attract the first portion (e.g., the first edge portion) of the convex substrate 504 to the surface 114-1, the second portion (e.g., the central portion) of the convex substrate 504 to the surface 114-2, and the third portion (e.g., the second edge portion) of the convex substrate 504 to the surface 114-3. After chucking the convex substrate 504, the convex substrate 504 may be flattened using the vacuum pressure from the vacuum source 132 via the vacuum chucking ports 125 and/or by actuating the actuators 118-1, 118-2, 118-3 to flatten the convex substrate 504. In some embodiments, the convex substrate 504 can be processed with or without flattening the convex substrate 504. In one or more examples, after processing the convex substrate 504, the convex substrate 504 can be dechucked by ceasing application of the DC bias to the pairs of electrodes 116-1, 116-2, 116-3 and/or by actuating the actuators 118-1, 118-2, 118-3 to dechuck the convex substrate 504.

Notably, the segments 112-1, 112-2, 112-3 and the actuators 118-1, 118-2, 118-3 facilitate processing of the concave substrate 404 and/or the convex substrate 504 without needing to flatten the concave substrate 404 and/or the convex substrate 504 before chucking. This increases efficiency of processing the concave substrate 404 and/or the convex substrate 504 and also avoids potential damage to the concave substrate 404 and/or the convex substrate 504 caused by the flattening process. Additionally, as noted above, the segments 112-1, 112-2, 112-3 and the actuators 118-1, 118-2, 118-3 can also be used for dechucking which can reduce risks of damaging the concave substrate 404 and/or the convex substrate 504 during the dechucking process.

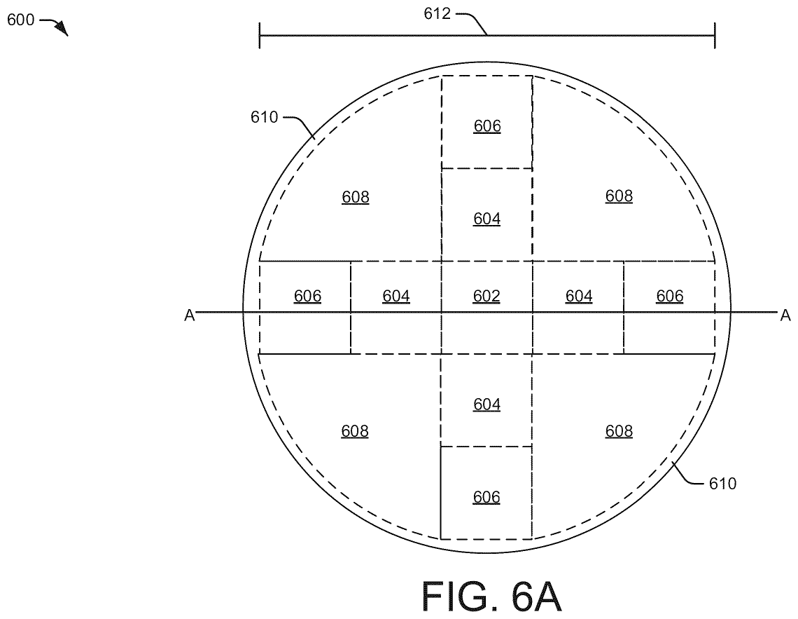

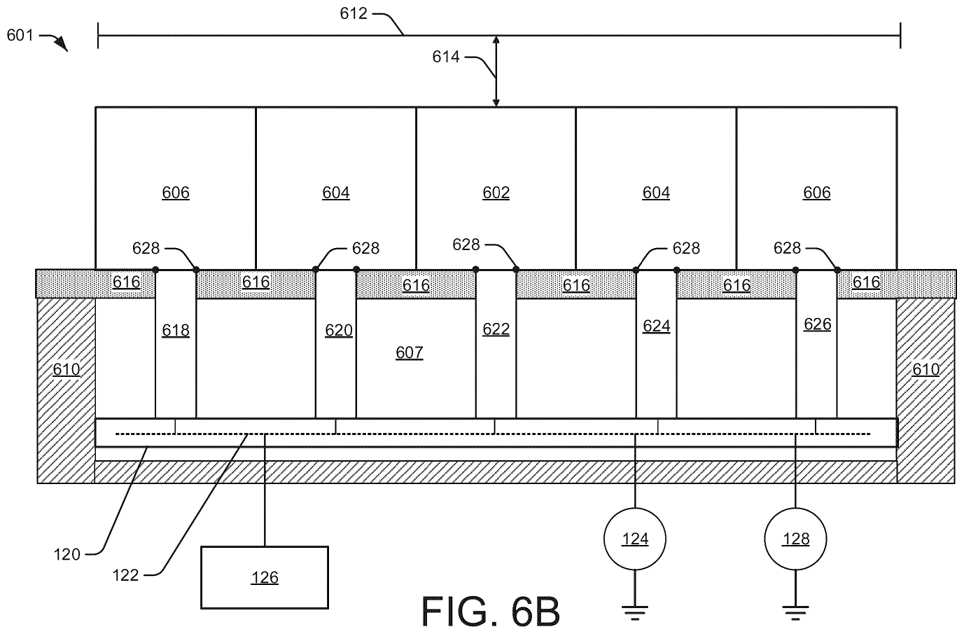

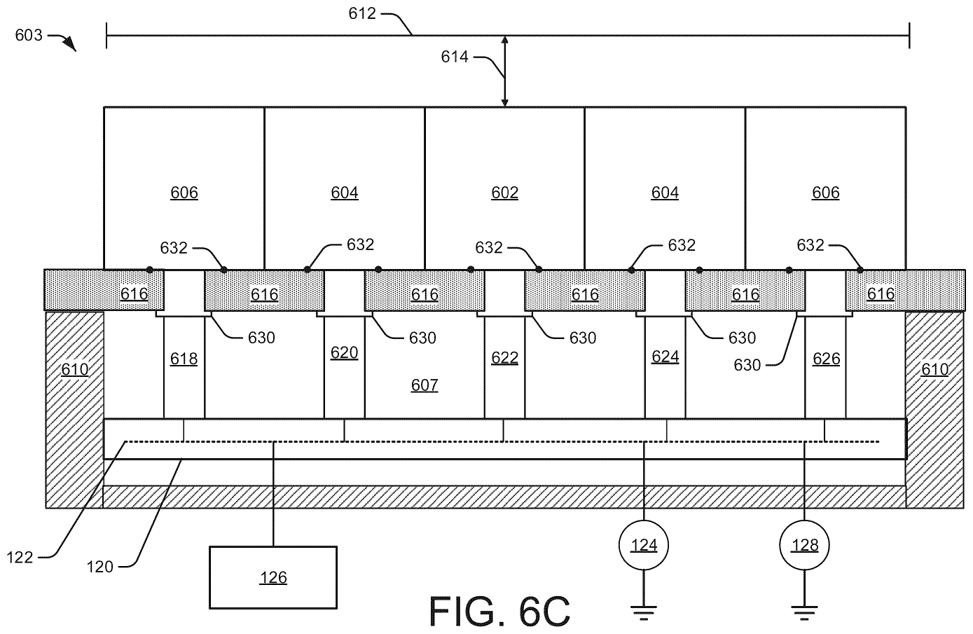

FIGS. 6A and 6B illustrate examples of a flexible membrane disposed below segments of a substrate support. FIG. 6A illustrates a top view 600 of the substrate support. As shown, the substrate support includes a center segment 602, middle segments 604, first edge segments 606, and second edge segments 608. In some embodiments, the center segment 602, the middle segments 604, the first edge segments 606, and the second edge segments 608 are disposed within a supporting structure 610. The supporting structure includes a diameter 612 which may have a length between 200 and 400 millimeters such as 300 millimeters. In one or more embodiments, the length of the diameter may be less than 200 millimeters or greater than 400 millimeters.

FIG. 6B illustrates a cross-sectional view 601 of the substrate support about line AA which is shown in FIG. 6A. The cross-sectional view 601 includes an extendable distance 614 which surfaces of the center segment 602, the middle segments 604, and the first edge segments 606 can extend relative to the supporting structure 610. In some embodiments, the extendable distance 614 may be a length in a range of 0.1 to 8.0 millimeters. In other embodiments, the extendable distance can be less than 0.1 millimeters or greater than 8.0 millimeters.

As shown in FIG. 6B, the center segment 602, the middle segments 604, and the first edge segments 606 are disposed on a membrane 616. In some embodiments, the membrane 616 includes a fluoroelastomer material such as a perfluoroelastomer material. In one or more embodiments, the membrane 616 is generally flexible such that a portion of the membrane 616 may deform if a force is applied to the portion. In various embodiments, actuators 618, 620, 622, 624, 626 are partially disposed in the membrane 616.

In certain embodiments, a portion of the actuators 618, 620, 622, 624, 626 are fixed to a portion of the membrane 616, for example, by an adhesive, an epoxy, a metal-joining process (e.g., welding, brazing, etc.), or the like to allow a seal and/or a bond to be formed between these components. In some embodiments, a portion of the center segment 602, the middle segments 604, and the first edge segments 606 are fixed to the membrane 616. In the illustrated example, adhesive joints 628 fix an extension portion of the actuators 618, 620, 622, 624, 626 and the center segment 602, the middle segments 604, and the first edge segments 606 to the membrane 616. In some embodiments, the adhesive joints 628 are used to form a seal between a portion of each of the actuators 618, 620, 622, 624, 626, the center segment 602, the middle segments 604, the first edge segments 606 and the membrane 616 to fluidly isolate the processing volume 108 from an internal region 607 of the substrate support disposed below the membrane 616 and within the inner surfaces of the supporting structure 610.

In various embodiments, the controller 126 is capable of controlling the transistors included in the PCB 120 to open or close electrical connections between the power supply 128 and the actuators 618, 620, 622, 624, 626. In one or more embodiments, supplying power to electrical components of the actuators 618, 620, 622, 624, 626 causes the actuator 622 to actuate the center segment 602; the actuators 620, 624 to actuate the middle segments 604; and the actuators 618, 626 to actuate the first edge segments 606.

The center segment 602 includes a pair of electrodes (not shown in FIGS. 6A-6B) which are electrically connected to one or more circuits formed in the circuit layer 122 of the PCB 120. Similarly, the middle segments 604 and the first edge segments 606 each include a pair of electrodes (not shown) which are each electrically connected to the circuit layer 122 of the PCB 120. The controller 126 can apply the DC bias to the pairs electrodes included in the center segment 602, the middle segments 604, and/or the first edge segments 606 in order to chuck the concave substrate 404 and/or the convex substrate 504.

FIG. 6C illustrates an additional cross-sectional view 603 of the substrate support about line AA which is shown in FIG. 6A. In some embodiments, the actuators 618, 620, 622, 624, 626 each include a flange 630 disposed below the membrane 616. In one or more embodiments, the membrane 616 is fixed to the bottom portions of the center segment 602, the middle segments 604, and the first edge segments 606. In the example illustrated in FIG. 6C, adhesive joints 632 fix a top portion of the membrane 616 to the bottom portions of the center segment 602, the middle segments 604, and the first edge segments 606, and the flanges 630 are configured to urge the membrane 616 and the center segment 602, the middle segments 604, or the first edge segments 606 to a desired position in the Z-direction (such as the vertical direction). In various embodiments, as the actuator 622 actuates the center segment 602 away from the PCB 120, a portion of the membrane 616 fixed to the bottom portion of the center segment 602 also actuates away from the PCB 120. In some embodiments, an actuation of the actuator 622 which actuates the center segment 602 away from the PCB 120 also actuates the flange 630 of the actuator 622 away from the PCB 120.

In various embodiments, the membrane 616 may be a flexible disk shaped member that has a diameter 612 and is manufactured from a polymer, metal or other useful material. In one example, the membrane 616 is formed from a metal material, such as Hastelloy, Haynes 202, various nickel alloys, stainless steel (SST), or the like. In certain embodiments, the membrane 616 may be manufactured from a material configured for use in aggressive etching configurations, such fluorine containing gas types of applications (e.g., for use in contact with fluorine). In one or more embodiments, the membrane 616 may include a coating (e.g., of a nickel alloy) configured for use in applications which also use fluorine.

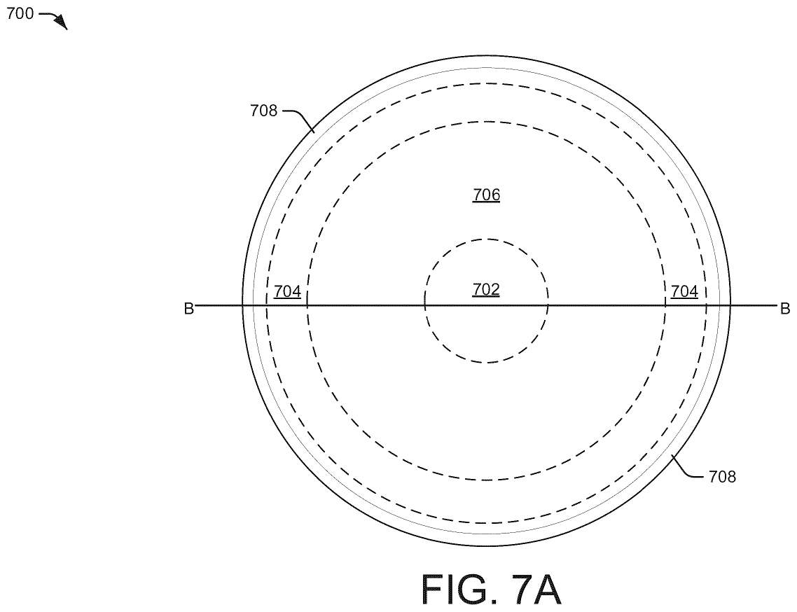

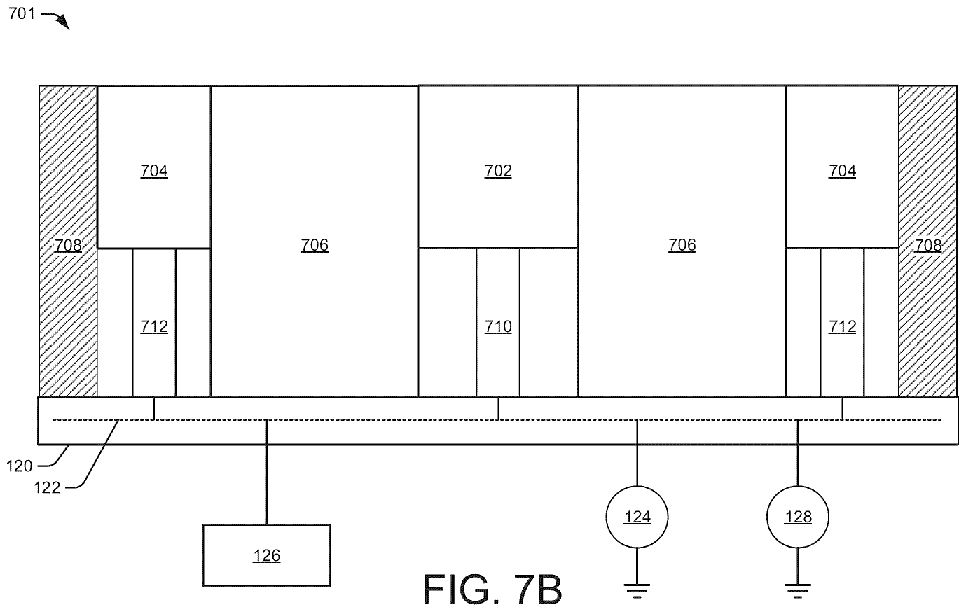

FIGS. 7A and 7B illustrate examples of an electrostatic chuck (ESC) including two segments. FIG. 7A illustrates a top view 700 of a substrate support of the ESC. As shown, the substrate support includes a first segment 702, a second segment 704, a non-moving portion 706, and a seal band 708. In some embodiments, the non-moving portion 706 is disposed between the first segment 702 and the second segment 704. In certain embodiments, the first segment 702 is configured to chuck the concave substrate 404 and the second segment is configured to chuck the convex substrate 504.

FIG. 7B illustrates a cross-sectional view 701 of the substrate support about line BB which is shown in FIG. 7A. The substrate support includes an actuator 710 configured to actuate the first segment 702 and at least one actuator 712 configured to actuate the second segment 704. In various embodiments, the at least one actuator 712 is representative of multiple actuators which collectively are capable of extending/retracting the second segment 704 relative to the non-moving portion 706. In some embodiments, the first segment 702 includes a pair of electrodes (not shown), and the second segment 704 includes at least one pair of electrodes (not shown). In one or more embodiments, the second segment 704 includes multiple pairs of electrodes (not shown). In some embodiments, the non-moving portion 706 includes one or more heaters 714 which may facilitate temperature control of the substrate support for thermal stability and thermal stress management of a substrate disposed on a surface of the substrate support.

In certain embodiments, the one or more processors of the controller 126 execute instructions which cause the one or more processors to control the transistors included in the circuit layer 122 of the PCB 120 in order to open/close electrical connections between the DC voltage source 124 and pairs of electrodes included in the first segment 702 and/or the second segment 704. In some embodiments, the instructions executed by the one or more processors of the controller 126 cause the one or more processors to control the transistors included in the circuit layer 122 in order to open/close electrical connections between the power supply 128 and electrical components of the actuator 710 and/or the at least one actuator 712. In an example of chucking the concave substrate 404, the controller 126 may supply power from the power supply 128 to electrical components of the actuator 710 to decrease a distance between a surface of the first segment 702 and a medial portion (e.g., a center portion) of the concave substrate 404. In an example of chucking the convex substrate 504, the controller 126 can supply power from the power supply 128 to electrical components of the at least one actuator 712 to decrease a distance between a surface of the second segment 704 and lateral portion (e.g., an edge portion) of the convex substrate 504.

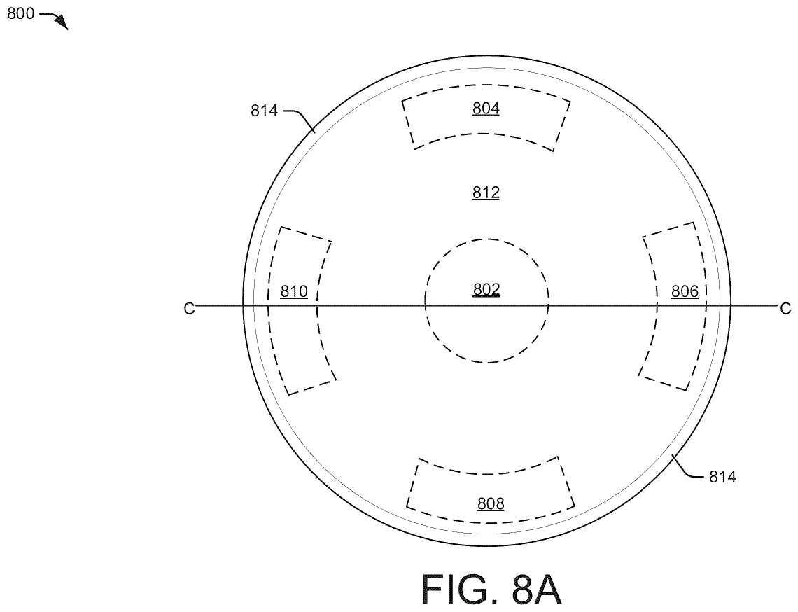

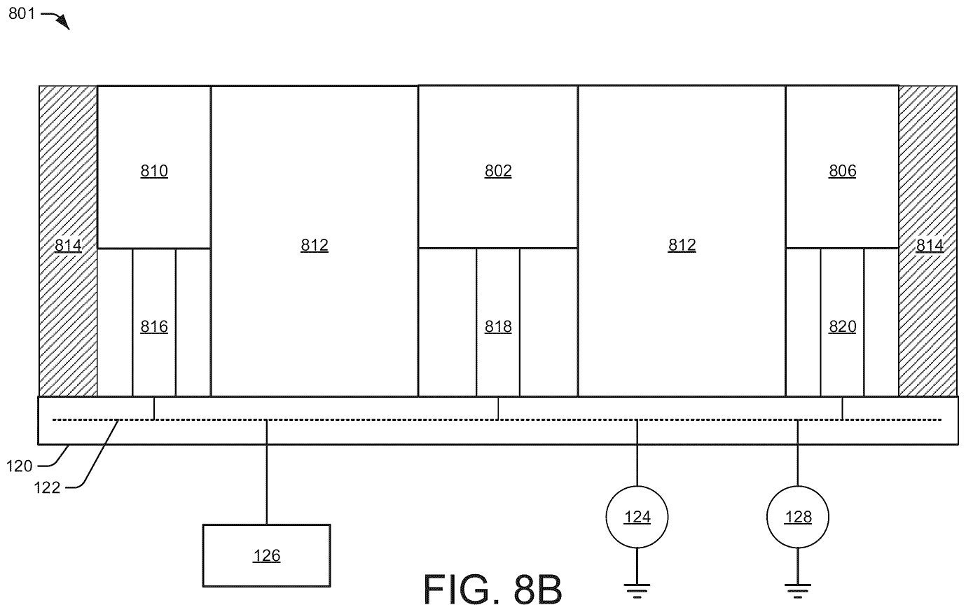

FIGS. 8A and 8B illustrate examples of an electrostatic chuck (ESC) including five segments. FIG. 8A illustrates a top view 800 of a substrate support of the ESC. The substrate support is illustrated to include a first segment 802, a second segment 804, a third segment 806, a fourth segment 808, a fifth segment 810, a non-moving portion 812, and a seal band 814. In some embodiments, the first segment 802 is disposed between the second segment 804, the third segment 806, the fourth segment 808, and the fifth segment 810. In one or more embodiments, the first segment 802 is configured to chuck the concave substrate 404 by use of an actuator 818 and one or more of the second segment 804, the third segment 806, the fourth segment 808, and the fifth segment 810 are configured to chuck the convex substrate 504 by use of one or more actuators, such as actuators 816 or 820.

FIG. 8B illustrates a cross-sectional view 801 of the substrate support about line CC which is shown in FIG. 8A. The substrate support is illustrated to include an actuator 816 for the fifth segment 810, an actuator 818 for the first segment 802, and an actuator 820 for the third segment 806. In some embodiments, the substrate support also includes an actuator for the second segment 804 (not shown) and an actuator for the fourth segment 808 (not shown). In various embodiments, the first segment 802 includes a pair of electrodes (not shown) electrically connected to the circuit layer 122; the second segment 804 includes a pair of electrodes (not shown) electrically connected to the circuit layer 122; the third segment 806 includes a pair of electrodes (not shown) electrically connected to the circuit layer 122; the fourth segment 808 includes a pair of electrodes (not shown) electrically connected to the circuit layer 122; and the fifth segment 810 includes a pair of electrodes (not shown) electrically connected to the circuit layer 122. In one or more embodiments, the non-moving portion 812 includes one or more heaters 822 which can facilitate temperature control of the substrate support for thermal stability and thermal stress management of a substrate disposed on a surface of the substrate support.

In some embodiments, the one or more processors of the controller 126 execute instructions which cause the one or more processors to control the transistors included in the circuit layer 122 of the PCB 120 in order to open/close electrical connections between the DC voltage source 124 and pairs of electrodes (not shown) included in the first segment 802, the second segment 804, the third segment 806, the fourth segment 808, and/or the fifth segment 810. In an example of chucking the concave substrate 404 (FIG. 4A), the one or more processors of the controller 126 may supply power from the power supply 128 to electrical components of the actuator 818 to decrease a distance between a surface of the first segment 802 and a medial portion (e.g., a center portion) of the concave substrate 404. In an example of chucking the convex substrate 504 (FIG. 5A), the one or more processors of the controller 126 can supply power from the power supply 128 to electrical components of one or more of the actuator 816, the actuator 820, the actuator for the second segment 804 (not shown), and the an actuator for the fourth segment 808 (not shown) in order to decrease a distance between a surface of at least one of the second segment 804, the third segment 806, the fourth segment 808, and the fifth segment 810 and a lateral portion (e.g., an edge portion) of the convex substrate 504.

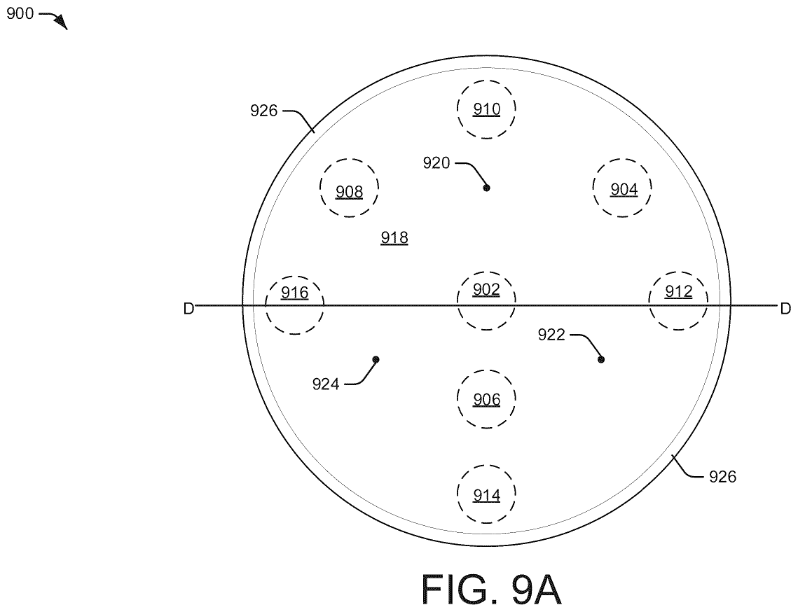

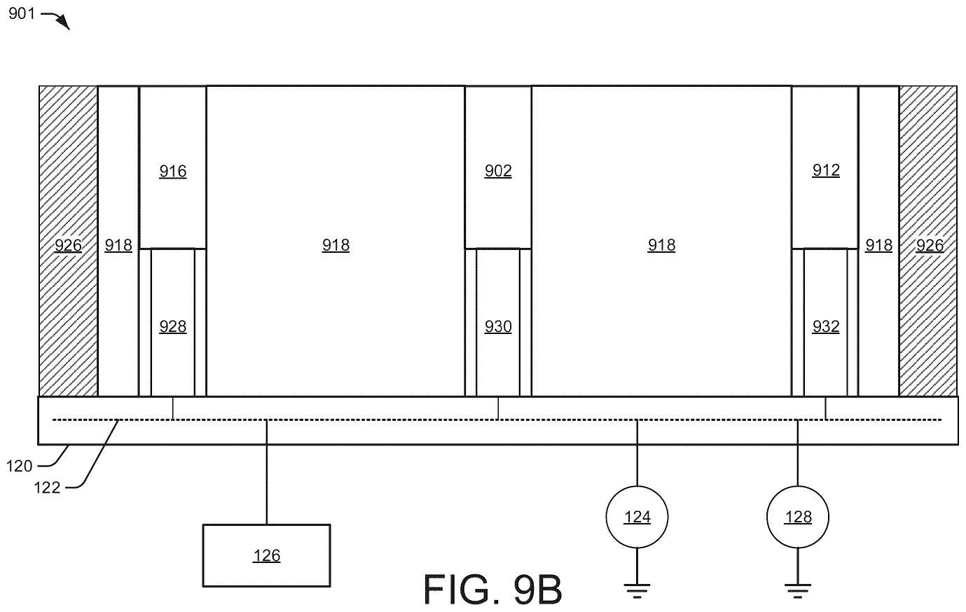

FIGS. 9A and 9B illustrate examples of an electrostatic chuck (ESC) including eight segments. FIG. 9A illustrates a top view 900 of a substrate support of the ESC. In the illustrated example, the substrate support includes segments 902, 904, 906, 908, 910, 912, 914, 916. The substrate support is also illustrated to include a non-moving portion 918, lift pins 920, 922, 924 disposed within the non-moving portion 918, and a seal band 926. In one or more embodiments, the lift pins 920, 922, 924 are configured to manipulate a portion of the concave substrate 404 and/or the convex substrate 504. In some embodiments, the lift pins 920, 922, 924 are configured to apply a force to a portion of the concave substrate 404 and/or the convex substrate 504 to reduce a distance between the portion of the concave substrate 404 and/or the convex substrate 504 and a surface of the non-moving portion 918. In various embodiments, the force applied to the portion of the concave substrate 404 and/or the convex substrate 504 may be a vacuum pressure (e.g., inner bores (not shown) of the lift pins 920, 922, 924 can be coupled to the vacuum chucking ports 125), a mechanical force (e.g., the lift pins 920, 922, 924 may include hooks or tabs), and/or another force. In some embodiments, the segments 902, 906 are configured to chuck the concave substrate 404. In certain embodiments, the segments 904, 908, 910, 912, 914, 914 are configured to chuck the convex substrate 504.

FIG. 9B illustrates a cross-sectional view 901 of the substrate support about line DD which is illustrated in FIG. 9A. As shown in FIG. 9B, the substrate support includes an actuator 928 for the segment 916, an actuator 930 for the segment 902, and an actuator 932 for the segment 912. In various embodiments, the substrate support also includes at least one actuator (not shown) for the segments 904, 906, 908, 910, 914. In some embodiments, the segments 902, 912, 916 each include a pair of electrodes (not shown) electrically connected to the circuit layer 122. In one or more embodiments, the segments 904, 906, 908, 910, 914 also each include a pair of electrodes (not shown) electrically connected to the circuit layer 122. In certain embodiments, the non-moving portion 918 includes one or more heaters 934 which can facilitate temperature control of the substrate support for thermal stability and thermal stress management of a substrate disposed on a surface of the substrate support.

In an example of chucking the concave substrate 404 (FIG. 4A), the one or more processors of the controller 126 execute instructions which cause the one or more processors to control the transistors in the circuit layer 122 in order to supply power from the power supply 128 to electrical components of the actuator 930 and/or an actuator for the segment 906 (not shown). In one or more embodiments, supplying power from the power supply 128 to the electrical components of the actuator 930 causes the actuator 930 to actuate a surface of the segment 902 towards a medial portion (e.g., a center portion) of the concave substrate 404 and decreases a distance between the surface of the segment 902 and the medial portion of the concave substrate 404. In an example of chucking the convex substrate 504 (FIG. 5A), the one or more processors of the controller 126 execute instructions which cause the one or more processors to control the transistors in the circuit layer 122 in order to supply power from the power supply 128 to electrical components of the actuators 928, 932 and/or actuators for the segments 904, 908, 910, 914 (not shown). In various embodiments, supplying power from the power supply 128 to the electrical components of the actuators 928. 932 causes the actuators 928, 932 to actuate surfaces of the segments 916, 912, respectively, towards a lateral portion (e.g., an edge portion) of the convex substrate 504. In some embodiments, actuating the surfaces of the segments 912, 916 towards the lateral portion of the convex substrate 504 decreases a distance between the surfaces of the segments 912, 916 and the lateral portion of the convex substrate 504.

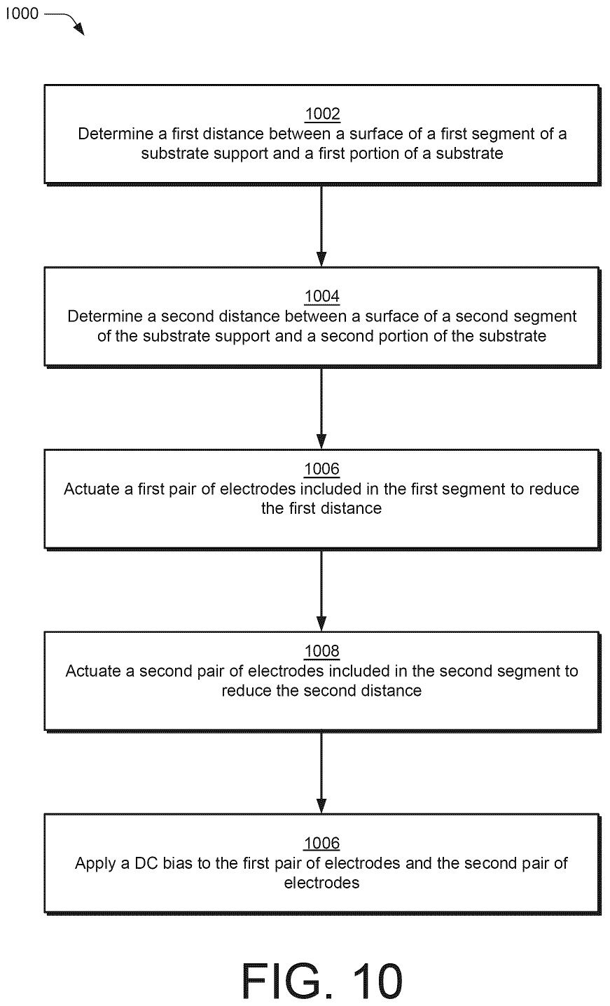

FIG. 10 is a flow diagram illustrating a method 1000 for substrate processing by chucking a substrate to a substrate support. At 1002, a first distance is determined between a surface of a first segment of a substrate support and a first portion of a substrate. In one or more embodiments, the distance between the first portion of the substrate (e.g., such as the distance 406 shown in FIG. 4A, or the distance 506 shown in FIG. 5A) and the surface 114-1 of the segment 112-1 is detected by the sensors 412, 414. In one or more embodiments, the first distance at 1002 may be a maximum distance or an average distance between the first portion of the substrate and the surface 114-1 of the segment 112-1.

At 1004, a second distance is determined between a surface of a second segment of the substrate support and a second portion of the substrate. In some embodiments, the distance between the second portion of the substrate (e.g., such as the distance 408 shown in FIG. 4A, or the distance 508 shown in FIG. 5A) and the surface 114-2 of the segment 112-2 is detected by the sensors 412, 414. In one or more embodiments, the second distance may be a maximum distance or an average distance between the second portion of the substrate and the surface 114-2 of the segment 112-2.

At 1006, a first pair of electrodes included in the first segment is actuated to reduce the first distance. In various embodiments, the controller 126 causes the actuator 118-1 to actuate the pair of electrodes 116-1 included in the segment 112-1 towards the first portion of the substrate to reduce a distance therebetween.

At 1008, a second pair of electrodes included in the second segment is actuated to reduce the second distance. In various embodiments, the controller 126 causes the actuator 118-2 to actuate the pair of electrodes 116-2 included in the segment 112-2 towards the second portion of the substrate to reduce a distance therebetween.

At 1010, a DC bias is applied to the first pair of electrodes and the second pair of electrodes. In one or more embodiments, the controller 126 causes the DC bias to be applied to the pair of electrodes 116-1 and the pair of electrodes 116-2 in order to generate the electrostatic forces to attract the first portion of the substrate to the surface 114-1 and to attract the second portion of the substrate to the surface 114-2.

In some embodiments of the method 1000, after applying the DC bias to the pairs of electrodes (i.e., performing operation 1010), the controller 126 is configured adjust the position of the segments of the substrate support by use of the actuators to cause the substrate to achieve a planar (e.g., flat) or near planar state during processing in the processing system. In one example, the surfaces 114-1, 114-2 and 114-3 of the segments are re-positioned so that the surfaces 114-1, 114-2 and 114-3 are positioned within a common plane. As discussed above, in some embodiments, during the dechucking process, which may be performed after chucking the substrate and positioning the substrate in a planar state, the controller 126 is configured re-adjust the position of the segments of the substrate support by use of the actuators to cause the substrate to re-deform back to its original deformed shape to avoid rapid spring-back of the substrate during the dechucking process. The rapid spring-back during the dechucking process can cause the substrate to be undesirably repositioned over the surface of the substrate support and/or cause damage to the substrate.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims. The recitation of identifiers such as (a), (b), (c) or (1), (2), (3) before steps in a method claim are not intended to and do not specify a particular order to the steps, but rather are used to simplify subsequent reference to such steps.

While the foregoing is directed to embodiments of the present disclosure, other and further embodiments of the disclosure may be devised without departing from the basic scope thereof, and the scope thereof is determined by the claims that follow.

We claim:

1. An electrostatic chuck (ESC) comprising:
a substrate support including a first segment and a second segment that is laterally adjacent to the first segment,
the first segment including a first pair of electrodes, the second segment including a second pair of electrodes, and the first segment being configured to be displaced vertically relative to the second segment to accommodate a non-planar surface of a substrate.

2. The ESC of claim 1, further comprising:
a third segment of the substrate support including a third pair of electrodes, and the third segment being configured to be displaced vertically relative to the first segment and the second segment.

3. The ESC of claim 1, wherein the first segment is configured such that vertical displacement of the first segment relative to the second segment is configured to translate the first segment both vertically and laterally relative to the second segment.

4. The ESC of claim 3, wherein the first segment is configured such that vertical displacement of the first segment relative to the second segment is configured to translate the first segment vertically upward and laterally away from the second segment to accommodate a concave surface of the substrate.

5. The ESC of claim 3, wherein the first segment is configured such that vertical displacement of the first segment relative to the second segment is configured to translate the first segment vertically upward and laterally toward from the second segment to accommodate a convex surface of the substrate.

6. The ESC of claim 1, wherein the first pair of electrodes is configured to generate a first electrostatic force between the first segment and a first portion of the substrate to chuck the first portion of the substrate to the first segment, and the second pair of electrodes is configured to generate a second electrostatic force between the second segment and a second portion of the substrate to chuck the second portion to the substrate to the second segment.

7. The ESC of claim 6, further comprising a membrane that is coupled to a side of the first segment and the second segment that is opposite from the substrate.

8. The ESC of claim 1, further comprising a diaphragm positioned over the first segment and the second segment such that the diaphragm covers an opening between the first segment and the second segment.

9. The ESC of claim 1, further comprising a first actuator that is configured to vertically displace the first segment and a second actuator that is configured to vertically displace the second segment.

10. A method for chucking a substrate to a substrate support comprising:
(a) determining a first distance between a surface of a first segment of the substrate support and a first portion of the substrate;
(b) determining a second distance between a surface of a second segment of the substrate support and a second portion of the substrate;
(c) actuating the first segment toward the first portion of the substrate to reduce the first distance;
(d) actuating the second segment toward the second portion of the substrate to reduce the second distance; and
(e) applying a DC bias to a first pair of electrodes included in the first segment and to a second pair of electrodes included in the second segment to chuck the first and second portions of the substrate to the first and second segments, respectively.

11. The method of claim 10, wherein (c) comprises displacing the first segment vertically within a processing volume, and wherein (d) comprises displacing the second segment in both vertically and laterally within the processing volume.

12. The method of claim 11, wherein the first segment is laterally adjacent to the second segment.

13. The method of claim 12, wherein (d) comprises displacing the second segment laterally toward the first segment.

14. The method of claim 13, wherein (d) comprises displacing the second segment laterally away from the first segment.

15. The method of claim 12, further comprising deforming a membrane that is positioned below the first segment and the second segment during (c) and (d).

16. The method of claim 12, further comprising deforming a diaphragm that covers a top surface of the first segment, a second surface of the second segment, and an opening between the first segment and the second segment.

17. An electrostatic chuck (ESC) comprising:
a substrate support including a first segment and a second segment that is laterally adjacent to the first segment;
a first actuator coupled to the first segment that is configured to vertically displace the first segment to reduce a distance between the first segment and a surface of a substrate;
a second actuator coupled to the second segment that is configured to vertically displace the second segment to reduce a distance between the second segment and the surface of the substrate;
a first pair of electrodes coupled to the first segment that, when energized, are configured to generate a first electrostatic force to urge the substrate toward the first segment; and
a second pair of electrodes coupled to the second segment that, when energized, are configured to generate a second electrostatic force to urge the substrate toward the second segment.

18. The ESC of claim 17, wherein the first actuator is configured to displace the first segment both vertically and laterally relative to the second segment.

19. The ESC of claim 18, further comprising a diaphragm positioned over the first segment, the second segment, and an opening between the first segment and the second segment, wherein the first pair of electrodes and the second pair of electrodes are positioned in the diaphragm.

20. The ESC of claim 18, further comprising a membrane positioned bellow the first segment and the second segment, wherein vertical displacement of the first segment or the second segment is configured to deform the membrane.
